(19) United States
(12) Patent Application Publication
(10) Pub. No.: US 2012/0227805 A1
(43) Pub. Date: Sep. 13, 2012

(54) SOLAR CELL

(75) Inventors: Martin Hermle, Freiburg (DE); Hubert Hauser, Freiburg (DE); Pauline Berger, Immenstaad (DE); Benedikt Blasi, Freiburg (DE); Marius Peters, Singapore (SG); Jan Christoph Goldschmidt, Freiburg (DE)

(73) Assignees: Fraunhofer-Gesellschaft Zur Förderung Der Angewandten Forschung E.V., Munchen (DE); ALBERT-LUDWIGS-UNIVERSITAT FREIBURG, Freiburg (DE)

(21) Appl. No.: 13/497,370

(22) PCT Filed: Sep. 13, 2010
(86) PCT No.: PCT/EP10/05596

§ 371 Date: May 24, 2012

(30) Foreign Application Priority Data
Sep. 21, 2009 (DE) 10 2009 042 018.5

(51) Int. Cl. H01L 31/0236

(52) U.S. Cl. 136/256

(57) ABSTRACT

A solar cell, having a silicon layer which has a dopant of a first dopant type, a front designed for the light coupling, and a rear. The silicon layer has a doped base layer, at least one textured layer and a metal layer being arranged on the rear of the silicon layer, optionally on additional intermediate layers, and the textured layer including a rear texture in at least a section thereof which rear texture is designed as an optical diffraction structure. At least one textured intermediate structure (3, 23, 33) is arranged between the textured layer (2, 22, 32) and the metal layer (4, 24, 34), the metal layer (4, 24, 34) being connected to the textured layer (2, 22, 32) and/or to the base layer (1, 21, 31) in an electrically conducting manner. The textured intermediate structure (3, 23, 33) is substantially transparent at least in the wavelength range of 800 nm to 1100 nm and has a refractive index n smaller than the refractive index of the textured layer in at least this wavelength range. The refractive index of all layers arranged between the base layer (1, 21, 31) and the textured intermediate layer (3, 23, 33) deviates by not more than 30% relative to the refractive index of silicon and the layer which is arranged directly on the rear of the base layer (1, 21, 31) is a passivation layer which passivates the surface with respect to the recombination of minority charge carriers.

### BACKGROUND

The invention relates to a solar cell comprising a silicon layer, which has a dopant of a first dopant type, a front embodied for light coupling, and a rear.

Such semiconductor silicon solar cells serve to convert electromagnetic radiation impinging the solar cell into electric energy. For this purpose, light is coupled into the solar cell via the front embodied for the light coupling such that by way of absorption pairs of electron holes are generated in the silicon layer. For this purpose, the silicon layer comprises a base doping and at a boundary to an oppositely doped emitter a pn-junction develops, at which the separation of the charge carriers occurs. The solar cell can be connected via electric contacts of the oppositely doped areas to an external power circuit.

In addition to the electric features, such as the ability of the surfaces for recombination and the material quality of the semiconductor layers, the luminous efficacy is essential for the effectiveness of a solar cell. The luminous efficacy represents the ratio between the electromagnetic radiation impinging the front in reference to the overall generation of pairs of electron holes due to the light-coupling in the solar cell.

Due to the fact that silicon is an indirect semiconductor and thus has lower absorption values for incoming radiation than direct semiconductors the extension of the light path inside the solar cell is particularly relevant for silicon solar cells in order to increase the luminous efficacy: Due to the lower absorption features a portion of the light with longer wavelengths penetrates the solar cell and impinges the rear of said solar cell. In order to increase the luminous efficacy it is therefore known to embody the rear of the solar cell in a reflective fashion such that a light beam impinging the rear is reflected back in the direction towards the front.

One option to improve the internal rear reflection is the use of diffraction structures in the sub-micrometer range. These cause photons reflected at the rear being reflected only in certain directions of diffraction. In the ideal case, the first order of diffraction extends almost parallel in reference to the rear surface so that the light path of the photons in silicon diffracted at the rear is strongly increased.

For example, a solar cell is known from WO 92/14270 embodied in several layers and here a textured layer is applied on a p-doped silicon layer which exhibits a texture embodied as an optic diffraction structure and on said textured layer in turn a metallic layer is applied.

This structure represents an optimization of the features for silicon solar cells of a layered structure, with the optimization occurring with regards to the light beams perpendicularly impinging the front of the layered structure.

However, when silicon solar cells are used typically light impinges the front of the solar cell not in perpendicular angles. Furthermore, typically in highly efficient wafer silicon solar cells the light coupling in and thus the luminous efficacy is increased by a front structure, for example in the form of inverted pyramids, because impinging radiation also impinges in the first reflection at least one additional front surface. This way, additionally a diagonal coupling in of light beams occurs, so that in reference to a planar surface a longer light path is achieved during the initial passage of the silicon layer until impinging the rear. However, these light beams overwhelmingly fail to impinge the rear in a perpendicular fashion.

Furthermore, in highly efficient wafer silicon solar cells the electric features, particularly the recombination characteristics, must be considered as well. An embodiment of the rear texture as an optic diffraction structure leads to an enlargement of the surface at the textured boundary of the rear so that an elevated overalls surface recombination at the rear has disadvantageous consequences for the overall effectiveness of the solar cell.

### SUMMARY

The invention is therefore based on the objective of creating a solar cell in which the rear is improved with respect to the optic and electric features. Furthermore, the solar cell according to the invention shall be characterized in a simple production.

This objective is attained in a solar cell according to the invention.

The solar cell according to the invention comprises a silicon layer, which exhibits a doping of a first doping type. This doping of the first doping type is therefore the base doping, i.e. the silicon layer represents a base layer. Furthermore, the solar cell comprises a front embodied for coupling in light and a rear.

At least one textured layer and one metal layer are arranged at the back of the silicon layer.

The textured layer comprises, at least in one partial area, a rear texture, which is embodied as an optic diffraction structure.

Such a diffraction structure is also called a deflective structure, i.e. the optic features of this texture are essentially described not by particle optics but by wave optics. The use of diffractive textures at the rear of a solar cell is generally known and described for example in WO 92/14270 or C. Heine, R. H. Morf, Submicrometer gratings for Solar energy applications, Applied Optics, VL. 34, no. 14, May 1995.

It is essential that at least one intermediate textured structure is arranged between the textured layer and the metal layer. The metal layer is connected to the textured layer and/or the base layer in an electrically conductive fashion. Furthermore, the intermediate textured structure is essentially transparent in the wavelength range from 800 nm to 1,100 nm, preferably at least in the wavelength range from 600 nm to 1,200 nm.

Here, essentially transparent means that the absorption coefficient α of the intermediate textured structure amounts to maximally 10⁴ cm⁻¹, beneficially maximally 10³ cm⁻¹, further preferred maximally 10² cm⁻¹. This condition applies for all wavelengths λ within the relevant range of wavelengths, preferably at least for the wavelength range from 800 nm to 1,100 nm, further preferred at least in the wavelength range from 600 nm to 1,200 nm.

At least in the range of wavelengths from 800 nm to 1,100 nm, preferably at least in the range of wavelengths from 600 nm to 1,200 nm, the intermediate textured structure has a diffraction index below the diffraction index of the textured layer.

The diffraction index (also called refraction number) is generally dependent on the wavelengths. Accordingly, a ratio of various diffraction indices n₁, n₂ therefore means that within the relevant range of wavelengths for each wavelengths λ the ratio between n₁(λ) and n₂(λ) applies respectively. The same is true for the absorption coefficient α.

The scope of the invention also includes that all additional intermediate layers are provided between the above-mentioned layers, if applicable. Here, it is essential that the layers, starting at the silicon layer, are arranged sequentially as silicon layer, textured layer, intermediate textured structure, metal layer.

Furthermore, in the solar cell according to the invention the layer immediately arranged at the rear of the base layer represents a passivation layer passivating the surface with regards to the recombination of minority charge carriers. This means that a low recombination speed of the minority surfaces is given at the boundary between the base layer and the layer immediately arranged on the base layer.

The diffraction index of all layers of the solar cell according to the invention arranged between the base layer and the intermediate textured layer maximally deviate by 30% from the diffraction index of silicon, with the diffraction indices of the above-mentioned layers may deviate from each other within the range stated. The above-mentioned conditions regarding the diffraction indices relate to the relevant range of wavelengths, preferably at least the range of wavelengths from 800 nm to 1,100 nm, further preferred at least in the range of wavelengths from 600 nm to 1,200 nm.

The reflection at the boundaries of these layers is reduced by this harmonization of the diffraction indices of all layers between the base layer and the intermediate textured layer so that the optic behavior of the rear is essentially determined by the diffraction structure and no undesired optic effects occur at other boundaries.

The solar cell according to the invention differs therefore from the solar cells of prior art in a diffraction structure being formed on the rear at a textured layer and at least one intermediate textured structure being arranged between the textured layer and the metal layer, essentially transparent in the above-mentioned range of wavelengths, having a diffraction index lower than the one of the textured layer. This way, the advantage develops that a stimulation of the surface plasmons in the metal layer by the absorbed radiation is reduced and/or other undesired absorption processes are also prevented, e.g., and on the other hand that the evanescent wave of the radiation diffracted at the textured side of the textured layer strongly reduces in intensity in the optically transparent intermediate textured structure. Consequently, this way a very high optic quality of the rear of the solar cell is achieved with regards to the diffraction of radiation in the above-mentioned range of wavelengths.

This way, for the first time the use of such a diffraction structure is possible in a highly efficient silicon solar cell, particularly in the combination with a refractive texture at the front of the solar cell, i.e. a texture which is essentially described by particle optics.

Furthermore, in the solar cell according to the invention the electric features and the optic features of the rear of the solar cell are separated, because the optic features are essentially determined by the texture of the textured layer in combination with the intermediate textured layer and the metal layer, while the electric features essentially being determined by the passivation layer. This way, an almost independent optimization of both features is possible, so that overall a solar cell is yielded with a very high optic and electric quality at the rear.

Preferably the intermediate textured structure is made from a single layer. However, the scope of the invention also includes that the intermediate textured structure comprises several individual layers and/or a composite material, which represents a spatial combination of different materials.

Advantageously the intermediate textured structure and/or additional layers arranged between the textured layer and the metal layer reduce any unevenness caused by the rear texture so that the metal layer is applied on a surface less uneven in reference to the surface of the rear texture, preferably on an essentially planar level.

In this preferred embodiment the solar cell comprises at its rear therefore both a textured layer with a texture embodied as a diffraction texture as well as an essentially planar metal layer. This way, the above-mentioned advantages for an increased optic quality are further enhanced because the stimulation of the surface plasmons in the metal is prevented.

The level differences of a texture embodied as a diffraction structure are typically greater than 50 nm. It is therefore particularly advantageous that the intermediate textured structure and perhaps additional layers arranged between the textured layer and the metal layer have an overall thickness of at least 50 nm, preferably that the intermediate textured structure has a thickness of at least 50 nm.

Preferably only the intermediate textured structure is arranged between the textured layer and the metal layer in order to prevent a negative influence upon the optic quality and/or the electric features of the solar cell.

For an optimization of the optic quality of the rear of the solar cell according to the invention it is advantageous that the diffraction index of all layers arranged between the base layer and the intermediate textured layer deviates maximally by 10%, preferably maximally by 5%, further preferred maximally by 1% from the diffraction index of silicon. The above-mentioned conditions regarding the diffraction indices relate to the relevant range of wavelengths, preferably the range of wavelengths from 800 nm to 1,100 nm.

The passivation layer is arranged preferably directly at the rear of the base layer such that the speed of surface recombination for carriers of minority charges is below 10⁴ cm/s, preferably below 10³ cm/s, particularly below 10² cm/s.

Preferably the passivation layer is undoped, in order to yield lower surface recombination speeds for minority charge carriers.

In particular, it is advantageous to embody the passivation layer from hydrogenated amorphous silicon (Si:H), with a particularly slow surface recombination speed being yielded for minority charge carriers when the passivation layer is embodied from intrinsic, amorphous, hydrogenated silicon (i-a-Si:H). The use of layers comprising hydrogenated amorphous silicon in solar cells is known per se and described for example in M. Taguchi et al. DOI 10.1002/pip.646.

Such a passivation layer combines the advantages of a very high passivation quality and a diffraction index almost identical to the one of silicon.

The solar cell according to the invention can be formed in several advantageous embodiments, with the emitter being able to be arranged at different positions of the solar cell. Additionally, the invention also comprises the embodiment of several emitters. The emitter may be embodied as a separate layer or as a diffusion within the base layer. Here, it is essential that the type of doping of the emitter is opposite to the type of doping of the base. Here, types of doping are n-doping and the opposite p-doping.

In a first variant of an advantageous embodiment of the solar cell according to the invention the textured layer is embodied as an emitter layer and doped opposite in reference to the base layer. Furthermore, at least one undoped pn-intermediate layer is arranged between the emitter layer and the base layer, by which a pn-junction develops between the emitter layer and the base layer. The emitter layer is embodied as an electrically conductive layer, at least with regards to the charge carrier majorities of the emitter layer.

Accordingly, in this preferred embodiment the emitter is arranged at the rear of a solar cell according to the invention and embodied as a textured layer. The intermediate pn-layer leads to a considerable reduction of recombinations at the pn-junction between the emitter layer and the base layer. Preferably, the intermediate pn-layer is therefore embodied as a passivation layer, as described above.

The contacting of the base layer occurs preferably via metal contacting structures applied on the front of the solar cell, for example in the form of the comb-shaped contacting grid known per se.

Preferably, no additional intermediate layers are arranged in the sequence of layers base layer/intermediate pn-layer/emitter layer in order to prevent any interference with the pn-junction forming.

The intermediate pn-layer preferably has a thickness of less than 10 nm, particularly a thickness of approx. 5 nm.

The intermediate textured structure is preferably embodied in an electrically conductive fashion so that a large-area contacting of the emitter layer occurs via the intermediate textured structure to the metal layer. Here it is particularly advantageous to embody the intermediate textured structure in a manner known per se from electrically conductive oxide (TCO, transparent conductive oxide), as described for example in M. Taguchi et al. DOI 10.1002/pip.646.

In a second variant of a preferred embodiment the intermediate textured structure is embodied in an electrically isolating fashion and the metal layer is connected at several local areas of the rear to at least the base layer in an electrically conductive fashion. In this advantageous embodiment the metal layer therefore represents the metal contacting of the base. Preferably the metal layer directly abuts the base layer at several local areas.

Therefore, in this advantageous embodiment contacting of the base occurs at several local areas of the rear. This way, on the one side a lower serial resistance of the base contacting can be achieved and on the other side, due to the contacting of the rear occurring only at a few local areas, a low overall surface recombination to the contacted areas can be achieved.

In particular, here it is advantageous to embody the rear contacting by local melting, for example as described in DE 100 46 170 A1 (so-called laser fired contacts, LFC).

Advantageously, in this preferred embodiment the textured layer is applied immediately on the base layer, in particular the textured layer is advantageously embodied as a passivation layer, as described above. This way, a high electric quality of the rear is yielded by the passivating effect of the textured layer at the boundary to the base layer, on the one side, and the smaller area covered with locally contacting areas in reference to the overall area of the rear.

In this preferred embodiment it is advantageous to embody the textured layer in an undoped fashion, particularly from intrinsic, amorphous, hydrogenated silicon and/or the intermediate textured structure from silicon dioxide or SiN or Al₂O₃.

In another, third variant of an advantageous embodiment the textured layer and the base layer comprise a doping of the same type of doping. Furthermore, at least one undoped base-texture intermediate layer is arranged between the textured layer and the base layer and the intermediate textured structure is embodied as an electrically conductive layer at least, with regards to the charge carrier majority of the textured layer.

In this advantageous embodiment the passivating effect of the rear of the base layer is therefore achieved by the undoped base-texture intermediate layer, which however is electrically conductive with regards to at least the charge carrier majorities. This may be achieved, for example, such that the base-texture intermediate layer is embodied with a thickness of less than 10 nm, particularly with a thickness of approximately 5 nm. Preferably the base-texture intermediate layer is embodied as a passivation layer, as described above, particularly advantageously from intrinsic, amorphous, hydrogenated silicon.

This embodiment has the advantage that simultaneously one passivation of the base is created and one passivation for the layer conducting the charge carrier majorities, which subsequently can be contacted over the entire area.

In this preferred embodiment preferably the textured layer is higher doped than the base layer so that a so-called back surface field (BSF) forms at the rear of the solar cell and this way additionally the speed of recombination is reduced at the rear and thus the electric quality of the rear of the solar cell is increased.

The intermediate textured structure is here preferably embodied from transparent, electrically conductive oxide (TCO). This leads to the advantage that a large-area electric contact is formed between the base layer and the metal layer so that a low contact resistance exists and simultaneously, due to the base-texture intermediate layer and/or the higher doping of the textured layer, an additional passivation effect is yielded at the rear of the solar cell.

Here, it may be advantageous, in order to increase the electric conductivity between the metal layer and the base layer, to additionally allow locally a metal layer directly abutting the base layer, for example as above-described via a local melting to create LFC.

In the above-mentioned advantageous embodiments of variants 2 and 3 the arrangement of the emitter occurs preferably at the front of the solar cell, for example by applying an emitter layer or by diffusing a doping opposite the base doping to form an emitter at the front of the solar cell.

The contacting of the emitter occurs preferably in a manner known per se by a metalizing structure applied to the front, for example a comb-shaped metalizing structure.

The base layer is preferably embodied from crystalline silicon substrate, particularly as a silicon wafer, and exhibits a thickness preferably ranging from 20 μm to 300 μm.

In case of local contacting of the base layer via the metal layer the production of a solar cell according to the invention comprises preferably the following processing steps:

Firstly, a surface cleaning of the rear of the base layer occurs. Subsequently a passivation layer is precipitated, preferably comprising intrinsic, amorphous, hydrogenated silicon.

If applicable, another doped, amorphous silicon layer is precipitated.

Subsequently the application of an etching template occurs to create the diffraction structure. Here, particularly the application of an embossing method known per se is advantageous, in which first a lacquer is applied and the structuring of the lacquer is performed by way of embossing.

Subsequently, the predetermined diffraction structure is created by way of etching the previously applied template.

Then the intermediate textured structure is applied, with a leveling of the diffraction structure occurring, and subsequently a metal layer is applied onto the intermediate textured structure, and a local contacting occurs, for example by way of local melting (LFC).

The production of a solar cell according to the invention with a base layer contacted over the entire surface comprises preferably the following processing steps:

After surface cleaning of the rear of the base layer, the precipitation of the passivation layer and a doped textured layer occurs, with the textured layer comprising the same type of doping as the base layer.

Subsequently, as described above, the texture is created by producing an etching template and etching the texture.

The diffraction structure created is leveled via the textured layer, with the textured layer being embodied in an electrically conductive fashion, e.g., as TCO.

Finally, the metal layer is applied onto the intermediate textured structure, preferably over the entire surface.

As described above, the solar cell according to the invention is particularly suitable for a combination with a refractive texture at the front and a diffractive texture via the diffractive structure at the rear.

The use of diffractive textures at the rear of a solar cell as described above is generally known and described for example in C. Heine, R. H. Morf, Submicrometer gratings for Solar energy applications, Applied Optics, V1. 34, no. 14, May 1995. In the silicon solar cells known from prior art no combination of refractive and diffractive textures occurs, though. Examinations of the applicant have shown that the essential disadvantage is caused such that in combinations of a front with a refractive texture and a rear with a diffractive structure light can impinge from different directions and with various relative orientations upon the rear so that a portion of the radiation impinges the rear texture at an angle, which is not optimal. Furthermore, radiation diffracted by the rear at least partially impinges the front at unfavorable angles such that a decoupling of this radiation occurs and thus the luminous efficacy is reduced. This effect is particularly distinct when the front structure represents a three-dimensional texture, as for example the texture known in prior art using inverted pyramids.

In an advantageous embodiment the front of the solar cell according to the invention therefore comprises, at least in a partial area, a front texture, which is periodic along a spatial direction A with a period length greater than 1 μm, and the rear comprises, at least in a partial area, a rear texture, which along a spatial direction B is periodic with a period length smaller than 1 μm. Here, the spatial direction A forms an angle with the spatial direction B from 80° to 100° degrees. In a top view of the front of the solar cell the spatial direction A of the period extension of the front texture and the spatial direction B of the periodic extension of the rear texture consequently form an angle from 80° to 100°.

A texture is called periodic when a vector V (V≠0) exists, for which it applies: a translation by V and an integer multiple of V transfers the texture onto itself. The creating vector of a period is the smallest possible vector V′ fulfilling this conditions. Periodicity is only given when such a smallest possible vector exists. It applies for V′ that exclusively translations of V′ and integer multiples of V′ transfer the texture onto itself. The length of V′ is the period length. A linear periodicity is given when there is only one such (linearly independent) vector. The front and rear textures preferably show such linear periodicity.

The spatial direction A here extends parallel to the front and the spatial direction B parallel to the rear. Here and in the following the term “parallel” relates to the respectively untextured surfaces of the front and rear, i.e. virtual planar levels, which would represent the untextured front and/or rear. Typically the front is parallel in reference to the rear. The statements “a spatial direction X extends parallel in reference to a plane E” shall be understood such that the vector representing X is located in the plane E, thus all points of X are also points of E.

In this advantageous embodiment the solar cell according to the invention comprises at the front a texture extending periodically in the spatial direction A. This way, the potential directions and orientations are reduced by which the radiation impinges the rear. Furthermore, the spatial direction B, with the rear texture extending periodically here, forms an angle from 80° to 100° with the spatial direction A. This way, the above-described negative effect of a shortened light path is excluded for the majority of the potential radiation paths.

Due to the embodiment of a front texture as a texture extending periodically in the spatial direction A, at least in case of radiation impinging the front perpendicularly, coupling in occurs essentially in a plane stretched by the spatial direction A and a spatial direction extending perpendicularly in reference to the front. This way it is possible to optimize the diffractive rear texture such
that the radiation diffracted at the rear propagate almost parallel in reference to said rear, thus an extension of the light path is achieved,
that the radiation diffracted at the rear impinges the front such that a total reflection is achieved at the front and thus also an extension of the light paths, and
that no loss-resulting multiple reflections occurs at the rear.

Such an optimization is partially achieved already by the spatial direction B, in which the rear texture extends periodically, exhibiting an angle from 80° to 100° in reference to the spatial direction A. An increased optimization is achieved by an angle from 85° to 95°, preferably an angle of 90°, i.e. the two spatial directions form a right angle in reference to each other.

Advantageously the front and rear textures each cover essentially the entire front and back of the solar cell, if applicable with interruptions e.g., in order to apply metalizing structures. Additionally the scope of the invention includes that only one or more partial areas of the front and/or rear exhibit a texture. In this embodiment the front and rear texture are preferably arranged in partial areas of the front and rear opposite each other.

The scope of the invention includes that, if applicable, the solar cell is divided at the front and/or rear into several partial sections, each of which having a texture extending periodically. However, it is essential that in other spatial directions than the spatial direction of the periodic extension any perhaps given repetitions exhibit an essentially larger periodicity compared to the periodicity of the periodically extending texture.

Preferably, the front texture exhibits no periodicity or a periodicity with a period length of at least 30 μm, preferably at least 50 μm in the spatial direction A′, perpendicular in reference to the spatial direction A. The spatial direction A′ also extends parallel in reference to the front. Furthermore it is advantageous for the front texture comprising in the spatial direction A′ no periodicity or a periodicity with a period length amounting to at least 5-fold, preferably at least 10-fold, further preferred at least 15-fold the period length of the front texture in the spatial direction A.

Furthermore, in a spatial direction B′, perpendicular in reference to the spatial direction B, the rear texture exhibits no periodicity or a periodicity with a period length of at least 5 μm, preferably at least 10 μm, further preferred at least 30 μm, particularly preferred at least 50 μm. The spatial direction B′ also extends parallel in reference to the rear. Furthermore it is advantageous for the rear texture to comprise no periodicity or a periodicity with a period length in the spatial direction B′ equivalent to at least 5-fold, preferably at least 10-fold, further preferred at least 15-fold the period length of the rear texture in the spatial direction B.

Furthermore it is advantageous when the textures in the spatial directions A′ and/or B′ exhibit no or only slight changes in height, i.e. that the elevation profile of the texture in this spatial direction does not change or changes only to an irrelevant degree.

Preferably, here the elevation of the front texture in the spatial direction A′ changes by no more than 2 μm, in particular the front texture has an approximately constant height in the spatial direction A′.

Furthermore, accordingly the height of the rear texture in the spatial direction A′ preferably changes by no more than 50 nm, particularly the rear texture has an approximately constant height in the spatial direction A′.

The above-mentioned conditions simplify the production process and prevent disadvantageous optic effects.

In order to simplify production and reduce the costs of the solar cell according to the invention it is particularly beneficial for the front structure to represent a texture extending linearly in the spatial direction A′ and/or the rear representing a texture linearly extending in the spatial direction B′. Such structures are also called groove structures. In this case, the spatial direction of the periodic extension is therefore perpendicular in reference to the linear or groove-like texture elements. In particular it is advantageous that the front texture in the spatial direction A′ and/or the rear texture in the spatial direction B′ each comprise an approximately constant cross-sectional area and an approximately constant cross-sectional shape.

It is within the scope of the invention that the texture is interrupted in partial areas at the front and/or the rear, for example in order to apply a metallization structure for the electric contacting of the silicon substrate.

The height of the front structure, i.e. the maximum height difference of the optically relevant area of the front structure ranges preferably from 2 μm to 50 μm, particularly from 5 μm to 30 μm. This way, an optimization of the refractive optic effect and the cost-effective production is yielded.

The height of the rear texture, i.e. the maximum difference in elevation of the optically relevant area of the rear texture, preferably ranges from 50 nm to 500 nm, particularly from 80 nm to 300 nm. This way, an optimization is achieved of the diffractive optic effect and the cost-effective production.

In order to prevent compromising the electric features of the solar cell and to allow a simple electric contacting via metallic structures it is advantageous for the front structure to exhibit a periodicity of less than 40 μm, preferably less than 20 μm.

In order to yield the best possible optic features for the rear it is alternatively and/or additionally advantageous for the rear texture to exhibit a periodicity greater than 50 nm, preferably greater than 100 nm.

Preferably the front texture is created directly at the front of the silicon substrate. Additionally, the scope of the invention includes to apply one or more layers to the front of the silicon substrate and to create the texture at one or more of these layers.

The periodicities of the front texture and the rear texture are preferably selected such that the front texture represents a predominantly refractive texture and the rear texture a predominantly diffractive texture. Advantageously the periodicity of the front is therefore greater than 3 μm, particularly greater than 5 μm. Alternatively or additionally the periodicity of the rear texture is advantageously below 800 nm, preferably below 600 nm.

In order to optimally increase the luminous efficacy the front texture covers advantageously at least 30%, particularly at least 60%, further at least 90% of the front, perhaps with interruptions, e.g., for metallization. The same applies for the rear texture at the rear.

In order to create highly efficient silicon solar cells the use of mono-crystalline silicon substrates is common. In this case, the front texture is preferably formed by linear texture elements, each of which respectively having a triangular cross-sectional area.

The use of multi-crystalline silicon wafers is also advantageous. Here, the yielded efficiency levels are slightly worse in reference to mono-crystalline solar cells, however the material costs are considerably lower. When using multi-crystalline silicon wafers advantageously a front texture is created with a cross-sectional area having curved or round edges.

Based on the different etching speeds in the different spatial directions when etching a mono-crystalline silicon substrate the rear texture preferably comprises linear texture elements, such as described in the above-mentioned publication J. Heine; R. H. Morf, l.c., on page 2478 regarding FIG. 3. However, frequently the production of such texture elements with serrated cross-sections is extremely expensive and costly. Preferably the serrated form is therefore approximated by a stair-step shape, as described in the above-mentioned publication on the same page regarding FIG. 4. The above-mentioned publication is included in this description by way of reference.

A crenellated rear texture with flanks extending perpendicular in reference to each other represent a particularly simple and therefore cost-effectively produced diffractive texture, such as described for example in the above-mentioned publication regarding FIG. 2.

Additionally, sinusoidal-shaped diffractive textures as well as serrated diffractive textures are included in the scope of the invention.

Due to the small structural sizes of the rear texture the above-mentioned advantageous cross-sectional shapes can frequently only be achieved by approximation, due to process technology, in particular frequently curves occur at the edges of the structures.

Contrary to the mentioned diffractive rear textures of prior art in the solar cell according to the invention, due to the front texture, the radiation impinges the rear typically not in a perpendicular fashion. Preferably the rear texture is therefore not optimized for a non-perpendicular irradiation of the rear, particularly when for a given incident angle θ upon the rear the periodicity A_{R} of the rear texture is selected according to formula 1:

$${Λ}_{R} = \frac{λ}{n cos ( θ )} \qquad ( Formula 1 )$$

with the diffractive index n of the silicon substrate and the wavelength λ of the radiation impinging the rear. Preferably here λ is the largest relevant wavelength, i.e. the largest still relevant wavelength of the spectrum contributing to the generation of charge carriers in the solar cell of the radiation impinging the solar cell and the angle θ represents the primary diffractive angle of the radiation on the rear given by the front texture. Formula 1 particularly provides optimal periodicity for the rear texture at an angle of 90° between the periodic extension of the front and rear textures and/or a front texture with triangular areas.

When using a mono-crystalline silicon wafer and etching of the front texture, due to the crystalline orientation, typically an incident angle θ develops on the rear amounting to 41.4°. Furthermore, the largest relevant wavelength is preferably selected with λ=1100 nm for silicon, because this represents a wavelength near the band gap. With a diffraction index of n−3.5 for silicon, in this advantageous embodiment therefore a periodicity of A_{R}=419 nm results.

### BRIEF DESCRIPTION OF THE DRAWINGS

In the following, additional features and preferred embodiments are explained using the figures and exemplary embodiments. Shown here are:

FIG. 1 a solar cell according to the invention in the above-described first variant of a preferred embodiment, in which the textured layer is embodied as an emitter layer;

FIG. 2 an exemplary embodiment of a solar cell according to the invention in the above-described second variant of a preferred embodiment, in which the textured layer is embodied as a passivating layer, and

FIG. 3 an exemplary embodiment of a solar cell according to the invention in the above-described third variant of an advantageous embodiment, in which a back surface field (BSF) is created via the doped textured layer.

### DETAILED DESCRIPTION OF THE PREFERRED EMBODIMENTS

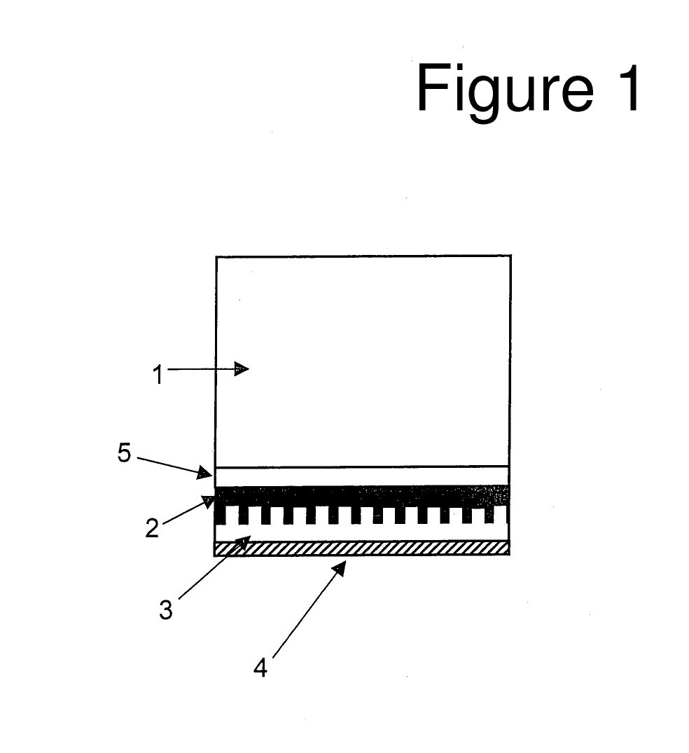

The exemplary embodiments of a solar cell according to the invention shown schematically in FIGS. 1 through 3 each comprise a base layer 1, 21, 31 embodied as an n-doped silicon wafer. The schematic illustrations in FIGS. 1 through 3 each show a partial section of the solar cell, i.e. the solar cell continues analogously at the right and the left edge. FIGS. 1 through 3 each show a partial cross-section in which the front is at the top and the rear of the solar cell is at the bottom. The solar cells shown are each embodied on a silicon wafer sized 20 cm×20 cm, with the silicon wafer showing a thickness of approximately 250 μm at a base doping of 10¹⁵ cm⁻³.

All three exemplary embodiments show at the front optic structures, extending linearly in the drawing plane from the right towards the left, which comprise a triangular cross-section perpendicularly in reference to the drawing plane so that, along the surface and perpendicularly in reference to the drawing plane, a groove shape develops as the surface progression of the front. This refractive front texture shows a periodicity of 10 μm, with the height of the texture elements amounting to approximately 14 μm.

Additionally, a textured layer 2, 22, 32 is arranged at the rear in all three exemplary embodiments, representing a diffractive texture each showing a crenellated progression in the cross-section, horizontally in reference to the drawing level of FIGS. 1 through 3. Perpendicularly in reference to the drawing plane in FIGS. 1 through 3 the rear texture respectively extends linearly.

The rear texture comprises a periodicity of approximately 420 nm.

The spatial direction of the periodic extension of the front texture is hereby aligned at an angle of 90° in reference to the spatial direction of the periodic extension of the rear texture, i.e. the linear progression of the front texture is aligned perpendicular in reference to the linear progression of the rear texture.

The height of the textured elements amounts to approximately 0.1 μm at the rear.

FIG. 1 is an exemplary embodiment according to the above-described first variant of a preferred embodiment. A pn-intermediate layer 5 is applied to the base layer 1 at the rear, having a thickness of approximately 5 nm and formed from intrinsic, amorphous, hydrogenated silicon. Here, a textured layer 2 is applied, which comprises a p-doped nano-crystalline silicon with a thickness of approximately 150 nm. The doping amounts to 10¹⁹ cm⁻³.

An intermediate textured layer 3 is applied on the textured layer 2, comprising electrically conductive, transparent oxide (TCO). It levels the unevenness caused by the texture such that a metal layer 4 ideally is applied as a planar layer upon the intermediate textured structure 3. At least the metal layer is applied essentially as a planar area compared to the surface of the textured layer.

A pn-junction forms via a pn-intermediate layer 5 between the base layer 1 and the textured layer 2 embodied as an emitter layer.

Radiation impinging the front is coupled in the base layer 1 and here absorbed, at least partially, such that pairs of electron holes are generated. The charge separation occurs at the pn-junction.

The majority charge carrier of the textured layer 2 embodied as an emitter layer is guided off via the electrically conductive intermediate textured structure 3 and the metal layer 4 acting as a metal emitter contact.

The majority charge carrier of the base layer 1 is guided off via comb-shaped metalizing structures (not shown) at the front of the solar cell.

The exemplary embodiment shown in FIG. 1 therefore provides the advantage that on the one hand the rear of the base layer 1 is passivated with a very high quality by the pn-intermediate layer 5. Additionally, the rear shows, due to the diffractive texture of the textured layer 2, a very high optic quality for radiation in the wavelength range from 600 nm to 1,200 nm so that even such radiation not absorbed by the initial passage of the base layer 1 contributes to the generation of pairs of electron holes, due to the considerably lengthened light path.

The high optic quality is here supported by the leveling of the texture via the intermediate textured structure 3 preventing the formation of plasmodes in the metal layer 4.

The metal layer 4 is made from aluminum.

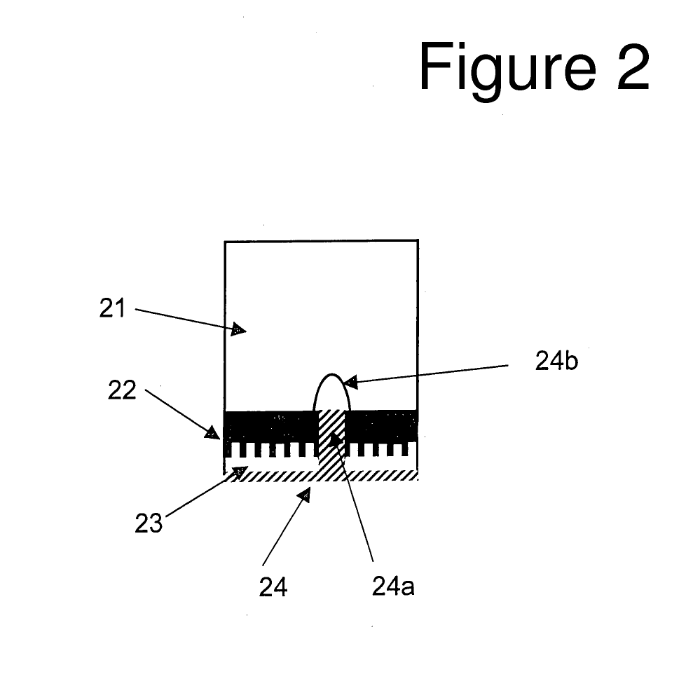

FIG. 2 shows schematically in a partial cross-section an exemplary embodiment of a solar cell according to the invention in a preferred embodiment of an above-described second variant.

The textured layer 22 is arranged directly at the rear of the base layer 21. The textured layer is here embodied from intrinsic, amorphous, hydrogenated silicon and thus also acts as a passivating layer for the electric passivation of the rear of the base layer 21.

The diffractive texture of the textured layer 22 and the refractive texture at the front of the base layer 21 are embodied analog the exemplary embodiment according to FIG. 1.

The intermediate textured layer 23 is embodied electrically insulating as a layer of silicon dioxide. The metal layer 24 comprising aluminum is applied thereon. In this exemplary embodiment the texture of the textured layer 22 is also leveled by the intermediate textured layer 23, so that the metal layer 24 is applied on a planar level.

The electric contacting of the base layer 21 occurs such that via a laser a local melting of metal layer 24, intermediate textured layer 23, textured layer 22, and a smaller partial area of the base layer 21 occurred so that upon the melted mixture setting the structure formed shown in FIG. 2. Here, the metal layer 24 abuts the local area 24a directly at the base layer 21 so that an electric contact is given. The area 24b here characterizes the area in the base layer 21 which was melted during the contacting process.

An emitter layer (not shown) is inserted by way of diffusion from a gaseous phase at the front of the base layer 21 and this emitter layer is electrically contacted via comb-shaped metallization structures (not shown).

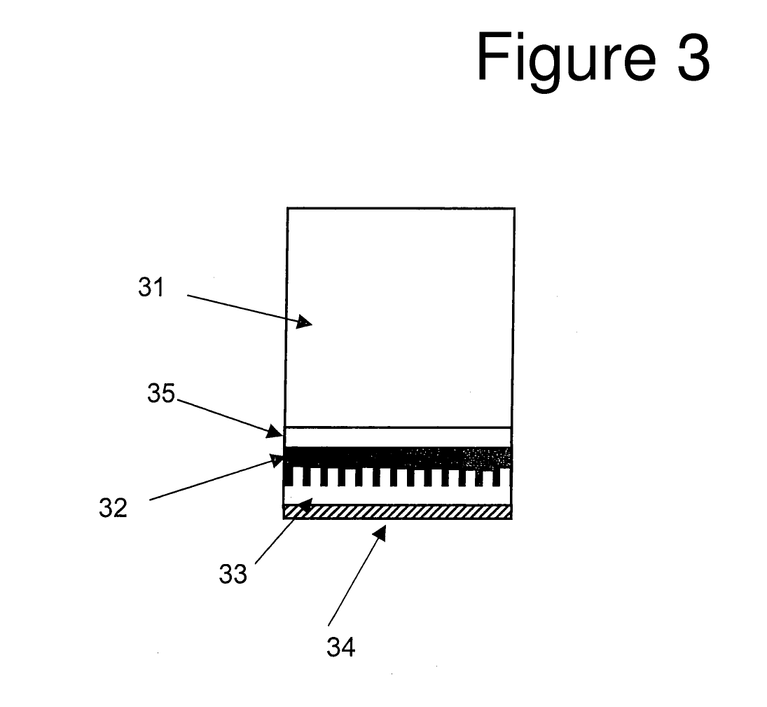

In the exemplary embodiment according to the above-described third variant of a preferred embodiment shown in FIG. 3 the refractive texture at the front of the base layer 31 and the diffractive texture of the textured layer 32 are also embodied according to FIG. 1. Additionally, an emitter layer is diffused at the front of the base layer 31 according to FIG. 2, which is electrically conducting and contacted by comb-shaped metallic contacting structures.

A base-texture intermediate layer 35 is arranged at the rear of the base layer 31. It is embodied in an electrically non-conductive fashion from intrinsic, amorphous, hydrogenated silicon and shows a thickness of approximately 5 nm.

The textured layer 32 is arranged on the base-texture intermediate layer 35 and also comprises a n-doping, i.e. a doping of the same doping type as the base layer 31. The textured layer 32 is however doped higher than the base layer 31, exhibiting a doping concentration of 10¹⁹ cm⁻³.

In this exemplary embodiment the rear of the base layer 31 is therefore electrically passivated in a dual fashion: on the one side a slow surface recombination speed is achieved by the base-texture intermediate layer 35 being formed as a passivation layer. On the other side a so-called back surface field (BSF) forms by the doped textured layer 31, which additionally reduces the recombination speed at the rear of the base layer 31.

The solar cell shown in this exemplary embodiment therefore shows a particularly high electric quality at the rear of the base layer 31.

The intermediate textured structure 33 is formed in an electrically conductive fashion from a transparent oxide (TCO) so that the majority charge carriers are guided off the base layer 31 via the metal layer 34.

Although the base-texture intermediate layer 35 is intrinsic, i.e. not electrically conductive; however, due to the low thickness of 5 nm at least the majority charge carriers of the base layer 31 can reach the textured layer 32 without any considerable electric resistance and the metal layer 34 via the textured intermediate structure 33 so that no loss occurs due to any potential serial resistance caused by the base-texture intermediate layer 35.

1. A solar cell comprising a silicon layer which has a doping of a first doping type, a front embodied for light coupling and a rear, with the silicon layer being a doped base layer (1, 21, 31) and at the rear of the silicon layer at least one textured layer (2, 22, 32) and one metal layer (4, 24, 34) being arranged, and the textured layer (2, 22, 32) comprising in a partial section a rear texture, which is embodied as an optic diffraction structure, between the textured layer (2, 22, 32) and the metal layer (4, 24, 34) at least one intermediate textured layer (3, 23, 33) is arranged, with the metal layer (4, 24, 34) being connected in an electrically conductive fashion with at least one of the textured layer (2, 22, 32) or with the base layer (1, 21, 31), the intermediate textured layer structure (3, 23, 33) is essentially transparent at least in a wavelength range from 800 nm to 1100 nm and has at least in this wavelength range a diffraction index n lower than a diffraction index of the textured layer, and a diffraction index of all layers arranged between the base layer (1, 21, 31) and the intermediate textured layer (3, 23, 33) deviates by maximally 30% from a diffraction index of silicon and a layer immediately arranged at the rear of the base layer (1, 21, 31) is a passivation layer passivating a surface in reference to a combination of minority charge carriers.

2. A solar cell according to claim 1, wherein the intermediate textured layer (3, 23, 33) is essentially transparent at least in the wavelength range from 600 nm to 1200 nm.

3. A solar cell according to claim 1, wherein at least one of the intermediate textured layer (3, 23, 33) or additional layers arranged between the textured layer (2, 22, 32) and the metal layer (4, 24, 34) reduce unevenness caused by a rear texture such that the metal layer (4, 24, 34) is applied on an area less uneven in reference to a surface of the rear texture.

4. A solar cell according to claim 1, wherein at least one of the intermediate textured layer (3, 23, 33) or additional layers arranged between the textured layer (2, 22, 32) and the metal layer (4, 24, 34) has a total thickness of at least 50 nm.

5. A solar cell according to claim 1, wherein the intermediate textured layer (3, 23, 33), at least in the wavelength range from 800 nm to 1100 nm, has on average a diffraction index n below 2.

6. A solar cell according to claim 1, wherein the passivation layer is a passivation layer passivating the surface with regards to a recombination of minority charge carriers, which at a boundary to the rear of the base layer (1, 21, 31) has a surface recombination speed for minority charge carriers below 10³ cm/s.

7. A solar cell according to claim 6, wherein the passivation layer is undoped.

8. A solar cell according to claim 6, wherein the passivation layer is formed from silicon.

9. A solar cell according to claim 6, wherein the textured layer (2) is an emitter layer and is doped opposite the base layer such that between the emitter layer and the base layer (1) at least one undoped pn-intermediate layer (5) is arranged by which a pn-junction forms between the emitter and base layer (1) and the emitter layer is formed as an electrically conductive layer at least with regards to charge carrier majorities of the emitter layer, and no additional intermediate layers are arranged in a sequence of layers: base layer/pn-intermediate layer/emitter layer.

10. A solar cell according to claim 9, wherein the pn-intermediate layer (5) is formed as passivation layer.

11. A solar cell according to claim 1, wherein the intermediate textured layer (23) is an electrically isolating and the metal layer (24) is connected at least at several local areas of the rear to the base layer (21) in an electrically conductive fashion.

12. A solar cell according to claim 11, wherein the textured layer (22) is applied immediately on the base layer (21), and the textured layer (22) is embodied as a passivation layer.

13. A solar cell according to claim 1, wherein the textured layer (32) and the base layer have a doping of the same doping type, at least one base-texture intermediate layer (35) is arranged between the textured layer (32) and the base layer (31) and the intermediate textured layer (33) is as an electrically conductive layer, at least with regards to charge carrier majorities of the textured layer (32), and no additional intermediate layers is arranged in a sequence of layers base layer/base-texture intermediate layer/textured layer/intermediate textured structure.

14. A solar cell according to claim 13, wherein the base-texture intermediate layer (35) is undoped.

15. A solar cell according to claim 13, wherein the textured layer (32) is higher doped than the base layer (31).

16. A solar cell according to claim 1, wherein the diffraction index of all layers arranged between the base layer (1, 21, 31) and the intermediate textured layer (3, 23, 33) deviates from the diffraction index of silicon, at least in the wavelength range from 800 nm to 1,100 nm by maximally 10%.

17. A solar cell according to claim 1, wherein an absorption coefficient α of the intermediate textured layer maximally amounts to 10⁴ cm⁻¹.
